(19) United States
(12) Patent Application Publication
(10) Pub. No.: US 2006/0279312 A1
(43) Pub. Date: Dec. 14, 2006

(54) Mini wave soldering system and method for soldering wires and pin configurations

(76) Inventors: Harold B. Kent, Portola Valley, CA (US); James J. Levante, Redwood City, CA (US); Aaron T. Fine, San Jose, CA (US); Joseph R. Layton, Sunnyvale, CA (US); Sarah Fox, San Jose, CA (US)

Correspondence Address: JONES DAY, 2882 SAND HILL ROAD, SUITE 240, MENLO PARK, CA, 94025, US

(21) Appl. No.: 11/377,817

(22) Filed: Mar. 15, 2006

Related U.S. Application Data
(60) Provisional application No. 60/662,453, filed on Mar. 15, 2005.

(51) Int. Cl. G01R 31/26

(52) U.S. Cl. 324/765

(57) ABSTRACT

A mini wave solder system includes a dielectric substrate having a hole defined therethrough, a conductive heat transfer pad, and a conductive retention pad. A conductive material is associated with the hole. The heat transfer pad and retention pad are disposed adjacent to the hole and the retention pad has a thermally activated conductive material positioned thereon. The heat transfer pad, retention pad, and hole are in thermal communication with each other. A method for coupling a component to a substrate utilizing this system is also described. A wire termination system includes a dielectric substrate having a surface, a conductive material disposed on the surface of the dielectric substrate comprising a retention pad and a heat transfer pad in thermal communication with each other, and a thermally activated conductive material positioned on the retention pad. When heat is applied to the heat transfer pad, thermal energy travels to the retention pad to melt the thermally activated conductive material in order to secure a component to the conductive material. A method for coupling a component to a dielectric substrate in a wire termination system is also described. A pin connection system for coupling a pin to a dielectric substrate is also described. The pin connection system includes a dielectric substrate having a hole and electrical traces defined on a surface of the substrate, a pin positioned in the hole, and a connection solder disposed on a top surface of the pin. The pin has at least one radial protrusion disposed on an outer periphery thereof for perpendicularly aligning the pin with the substrate and for retaining the pin in the substrate in a substantially immobile manner. The connection solder at least one of strengthens the mechanical connection of the pin to the substrate and electrically connects the pin to the traces on the substrate.

### FIELD

This disclosure generally relates to soldering techniques and more particularly to a method of soldering a fine wire using a “mini wave” soldering method as well as various implementations of pin retention.

### BACKGROUND

The miniaturization trend in electronics has been under way for many years and has, in particular, revolutionized the minimally invasive medical device. Along with the advances have come some manufacturing problems. One example of this is in the extremely fine electrical wires used in newer medical catheters. The wire sizes are almost always smaller than 0.005 inches in diameter and usually only 0.002 inches in diameter (smaller than the diameter of a human hair).

Wire sizes this small pose extra challenges for assembly technicians. Normal insulating techniques do not apply to wires this small and the insulations used are very difficult to remove without damaging the wires themselves. Once all the wires are successfully stripped, wire management becomes an issue, especially with 27 to 76 wires per connector.

Traditional termination techniques are insufficient for terminating the fine wires of modem catheters. Solder cups are far too bulky and don't allow for easy wire management. Installing a wire in a clip and gluing the wire in place is impractical because “clips” for wires this small are not readily available. Crimping another device onto the end of one of these wires is impractical due to the fragility of the wires involved: crimping one of these wires is more likely to break the wire than it is to form a mechanical bond. The ideal fine wire termination system would incorporate a wire management system, low wire stress assembly, easy rework-ability, quick joint inspection, and use the same tools already present in the manufacturing environment.

Additionally, high density connectors are at a premium for space, especially for wire terminations or the addition of components such as resistors and capacitors. Generally, attaching a wire to a given pin precludes the possibility of adding a component to that pin. This is especially true with the solder cups that are found on the majority of high density connectors currently in widespread use. Therefore, the ideal connector system will have separate wire terminations and interconnect devices. By separating the two, it is possible to spread failure points across multiple devices, which helps in later rework and increased yields. By attaching both devices to a third interstitial member, it is possible to easily add components without taking up any wire termination ports inside the connector.

### SUMMARY

A mini wave soldering system and hot bar termination system are described. In addition, various pin constructions for use in a PCB or other substrate are described, as well as a pin connection system.

### BRIEF DESCRIPTION OF THE DRAWINGS

FIG. 1 is a cross-sectional view of a basic example mini wave solder system;

FIG. 2 is a cross-sectional view of an example mini wave solder system having a solder mask to prevent contamination;

FIG. 3 is a cross-sectional view of an example mini wave solder system having heat transfer solder to facilitate the transfer of heat;

FIG. 4 is a cross-sectional view of an example narrow mini wave solder system;

FIG. 5 is a cross-sectional view of an example basic narrow mini wave solder system with solder mask to prevent contamination;

FIG. 6 is a cross-sectional view of an example narrow mini wave solder system with solder mask and heat transfer solder;

FIG. 7 is a cross-sectional view of an example double mini wave solder system;

FIG. 8 is a perspective view of an example hot bar pad wire termination system;

FIG. 9 is a perspective view of an example hot bar pad wire termination system with heat transfer solder;

FIG. 10A is a plan side view of an example pin;

FIG. 10B is a perspective view of the example pin of FIG. 10A with a cutaway portion showing the bore in the top end of the pin;

FIG. 11 is a cross-sectional view of an example barbed pin positioned in a plated through hole;

FIG. 12 is a cross-sectional view of an example barbed pin positioned in a plated through hole with solder;

FIG. 13 is a cross-sectional view of an example barbed pin positioned in a plated through hole with counterbore;

FIG. 14 is a cross-sectional view of an example barbed pin positioned in a plated through hole with a clip;

FIG. 15 is a cross-sectional view of an example barbed pin positioned in a plated through hole with a clip and solder;

FIG. 16 is a cross-sectional view of an example raised barbed pin positioned in a plated through hole;

FIG. 17 is a cross-sectional view of an example raised barbed pin positioned in a plated through hole with solder;

FIG. 18 is a cross-sectional view of an example tapered tipped pin positioned in a plated through hole;

FIG. 19 is a cross-sectional view of an example tapered tipped pin positioned in a plated through hole with solder;

FIG. 20 is a cross-sectional view of an example wire-form pin positioned in a non-plated through hole;

FIG. 21 is a cross-sectional view of an example wire-form pin positioned in a non-plated through hole with solder;

FIG. 22A is a plan side view and a top view of an example pin having a boss;

FIG. 22B is a plan side view and a top view of an example tapered pin;

FIG. 22C is a plan side view and a top view of an example pin having an asymmetric head;

FIG. 22D is a plan side view and a top view of an example pin having a polygonal head;

FIG. 22E is a plan side view and a top view of an example pin having a triangular head;

FIG. 22F is a plan side view and a top view of an example pin having a square head;

FIG. 22G is a plan side view and a top view of an example double formed pin;

FIG. 22H is a plan side view and a top view of an example knurled pin;

FIG. 221 is a plan side view and a top view of an example quad formed pin;

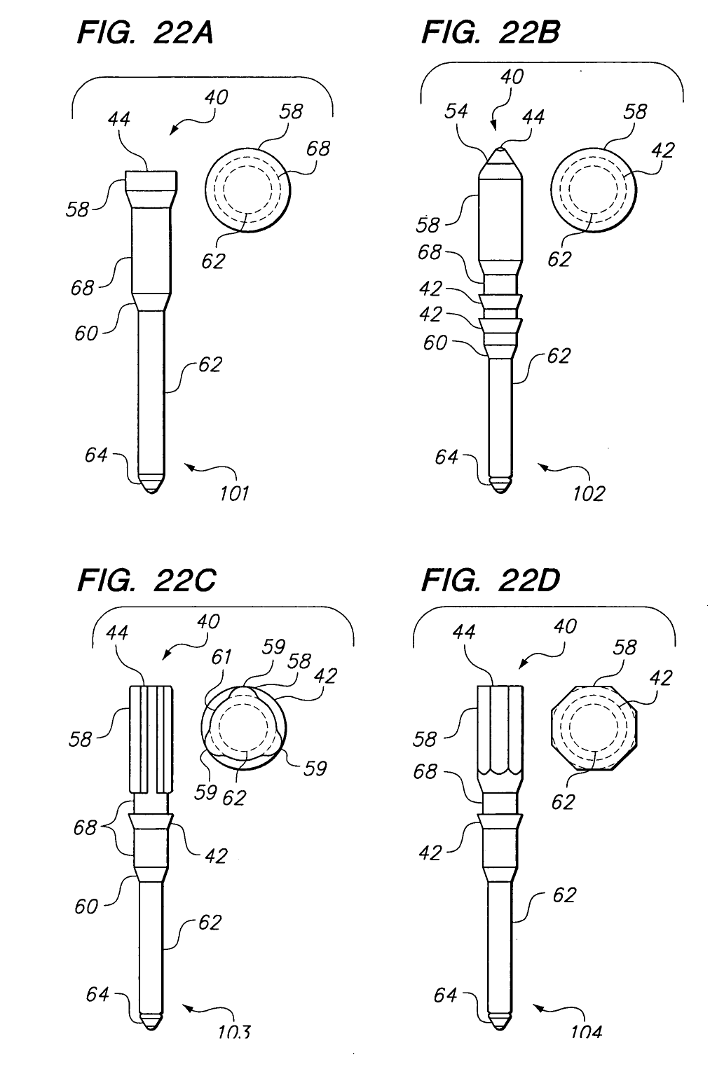

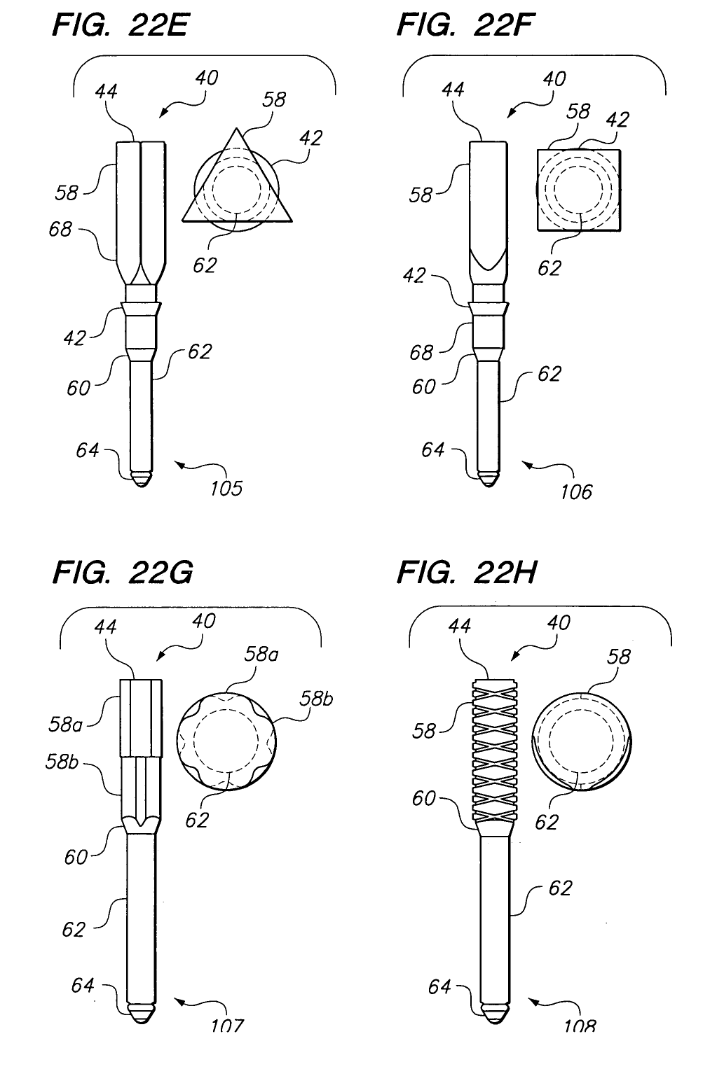

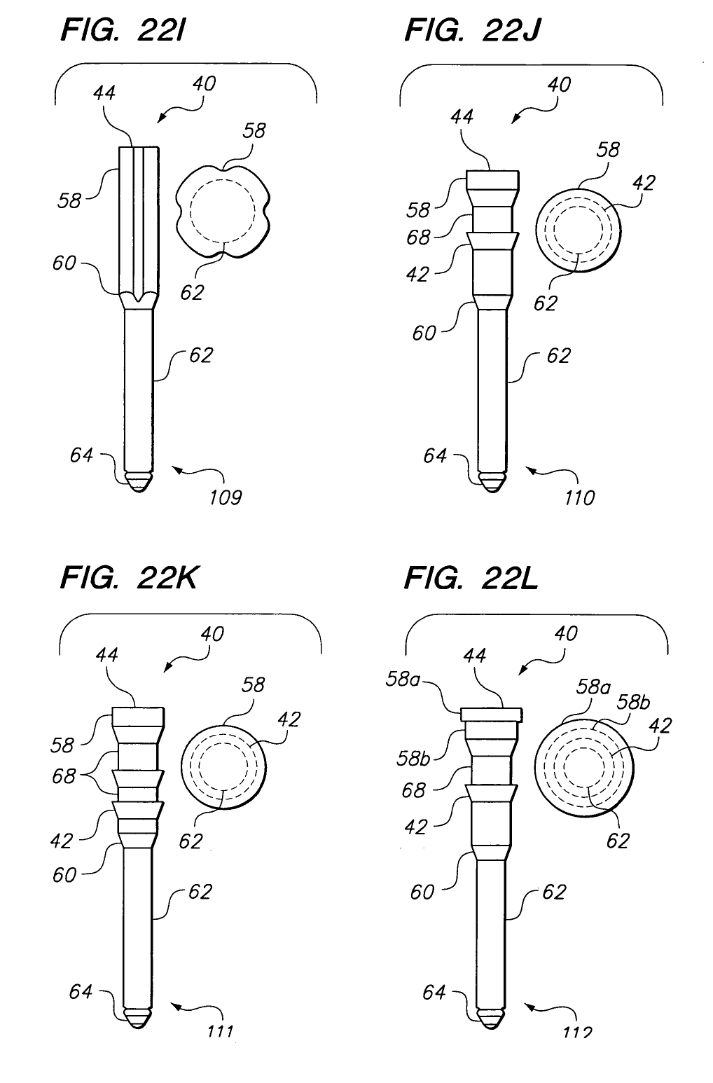

FIG. 22J is a plan side view and a top view of an example pin with a boss and a single barb;

FIG. 22K is a plan side view and a top view of an example pin with a boss and multiple barbs; and

FIG. 22L is a plan side view and a top view of an example pin with a top hat boss and single barb.

### DETAILED DESCRIPTION

A mini wave solder system utilizes a dielectric substrate that has a hole defined therein. The hole may be a through hole or a blind hole. In many of the below described examples, the hole has an inner conductive wall. The inner conductive wall may be provided by plating or otherwise coating a conductive material on the wall, or by inserting a conductive material into the hole, such as an eyelet or clip. A heat transfer pad is positioned adjacent to an opening of the hole. In addition, a retention pad is positioned adjacent to the opening of the hole in the vicinity of the heat transfer pad. The heat transfer pad and retention pad are formed from a conductive material coupled to the dielectric substrate. The conductive material of the heat transfer pad and retention pad is in communication with the conductive material in the hole. The hole, heat transfer pad, and retention pad are in thermal communication with each other through the conductive material. In one example, the conductive material inside the hole, on the retention pad, and on the heat transfer pad is copper. In another example, the material may be another conductive material. The materials inside the hole, on the retention pad, and on the heat transfer pad may be the same or different, as long as they are thermally conductive. In addition, the materials, if different, may have different thermal conductivity levels and/or different electrical conductivity levels.

Connection material can be applied to the retention pad and is melted when heat is applied to the heat transfer pad from an external source. The heat transfer pad may include a heat transfer material that melts and enhances the thermal communication of the system. A wire is inserted into the hole before the application of the heat source and melted connection material flows from its initial starting place towards the heat source, encapsulating the wire in the process. After the heat source is removed from the heat transfer pad, the connection material cools and hardens to mechanically connect the wire to the hole. The wire is then in electrical communication with the conductive walls of the hole and hence with other entities on the substrate that are in electrical communication with the hole.

A secondary dielectric may be applied to the dielectric substrate between the opening of the hole and the heat transfer pad. The secondary dielectric prevents connection material from entering the heat transfer pad and vice versa. The heat transfer pad may be narrower than the retention pad in order to encourage the aforementioned encapsulation by reducing the area available for the connection material to move when melted by the heat source.

A termination system is also disclosed. The system comprises conductive material disposed on a surface of a dielectric substrate. The conductive material has a retention pad and an optional heat transfer pad in thermal communication therewith. Connection material is applied to the retention pad and optionally to the heat transfer pad. A secondary dielectric may be disposed between the retention pad and the heat transfer pad to prevent the connection material from flowing to the heat transfer pad. In this respect, when heat is applied to the heat transfer pad, the connection material melts. A flat, round, stranded, or other type of wire or component lead can be inserted into the melted connection material. After the heat source is removed, the connection material hardens to thereby connect the wire to the retention pad and hence to the underlying conductive material and whatever other entities the conductive material may be in electrical communication with. Heat transfer connection material can be applied to the heat transfer pad in order to facilitate transferring heat between the heat source and the heat transfer pad. It is also possible to directly heat the connection solder without the need or use of the heat transfer pad or the heat transfer connection material.

A pin for insertion into a feature of a dielectric substrate is further disclosed. The pin typically has at least one barb formed on an outer circumference thereof, but other examples do not utilize barbs. The outer surfaces frictionally engage an interior side wall of the hole. This engagement can provide for alignment, retention, thermal communication, electrical communication, or any combination of the above. The pin may include a hollow bore formed therein and may also optionally contain a secondary entity configured to mechanically interact with an inserted conductive member. The hole may have a conductive inner wall and the pin may be covered in whole or in part with solder to facilitate both retention and any desired electrical communication.

Various other methods of pin to hole frictional engagement are also herein described. Pins may be machined, stamped, swaged, or otherwise formed and the holes in the dielectric are not limited to purely circular constructions. It should also be noted that while it is advantageous to combine all of the above features, each can be used separately to good effect in any wire termination or connection system.

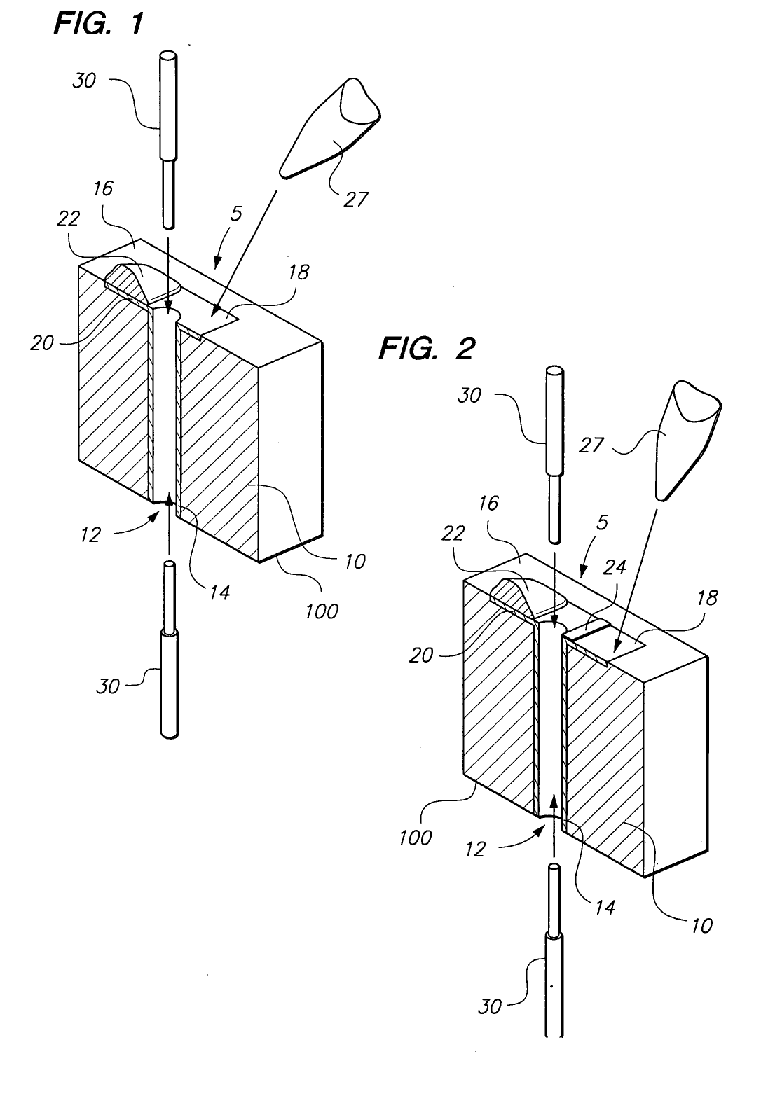

Referring to the drawings, FIG. 1 illustrates a mini wave wire termination system 5. System 5 is used to connect a fine wire to the conductive traces of a printed circuit board (“PCB”) 10 or other dielectric substrate. Formed within substrate 10 is hole 12. The interior walls of the hole 12 are coated with a conductive material 14. Furthermore, conductive material 14 extends from the hole to a top surface 16 of substrate 10 and a bottom surface 100 of substrate 10. The conductive material 14 may be applied to the surfaces of the dielectric substrate. A known method for applying the conductive coating is by plating a material, such as copper, onto the surface. The terms conductive coating and conductive plating are used interchangeably herein to refer to a conductive material deposited on a surface by any known means of application. In addition, any conductive material known to those of skill in the art may be utilized with the examples described herein. Copper is only one such material. Different types of conductive material having the same or different levels of conductivity may be used in a single example. Moreover, conductive material may be applied to the surfaces in any known way, including, but not limited to electro-plating, electro-less plating, printing, etching, and the like. Also, the term PCB, as used herein, is defined to include any dielectric substrate, and is not limited to a printed circuit board.

The conductive plating 14 extends to the top surface 16 of the substrate 10 to define a conductive pad that includes the heat transfer pad 18 and solder retention pad 20, which are usually disposed on opposite sides of the opening of the hole 12. Part of the conductive pad joins the heat transfer pad 18 and the retention pad 20 thermally. In this respect, the heat transfer pad 18, solder retention pad 20 and the conductive plating within hole 12 are in at least thermal communication and, oftentimes electrical communication with each other. Typically, the heat transfer pad 18 and the solder retention pad 20 are generally rectangular, but it will be recognized that other shapes are possible. In addition, while the hole 12 is shown as circular in the figures, it will be recognized that any shape may be used for the hole, including arcuate and polygonal, among other shapes. Connection material or solder 22 is disposed on solder retention pad 20. It is to be understood that solder refers to the general term and not the specific example and could in fact be any thermally activated conductive material. The term connection material may be used interchangeably herein with the term connection solder or solder. Each of these terms refers to a thermally activated conductive material. Thus, as used herein, each of the terms connection material, connection solder, and solder should be understood to generically refer to a thermally activated conductive material.

In order to attach a fine wire to a substrate 10, a stripped, and possibly twisted and tinned wire is inserted into the hole 12. Next, the tip of a soldering iron or other heating element 27 contacts the heat transfer pad 18 to initiate the thermal communication between conductive plating 14, hole 12, and solder retention pad 20. The heat melts connection solder 22 such that it flows over and around the wire previously inserted into hole 12. The connection solder 22 flows over the pad area surrounding the opening of hole 12 as connection solder 22 moves from its initial deposition location towards the source of heat. After connection solder 22 has encapsulated the fine wire, the heat source is removed and connection solder 22 is allowed to cool and harden. This connects the wire to hole 12.

In order to prevent connection solder 22 from flowing back to the heat source, a top, secondary dielectric or solder mask 24 may be positioned between the heat transfer pad 18 and the hole 12 over a portion of the conductive material 14 that is positioned on the top surface 16 of the substrate 10. A secondary dielectric may lie over cooper and another dielectric insulator and may be formed from either exposed, laminated, film, or a hardened photosensitive polymer.

Referring to FIG. 2, secondary dielectric or solder mask 24 is placed between the heat transfer pad 18 and the hole 12. Solder mask 24 provides a barrier between the soldering iron tip when placed on the heat transfer pad 18 and the melted connection solder 22. In this respect, it is possible to prevent contamination of the connection solder 22 from the heat source itself and allow for moving between leaded and lead free soldering applications with the same heat source.

Although not shown, the heat transfer pad 18 could be connected to more than one retention pad 20, with each of the retention pads in communication with the hole. The heat transfer pad 18 could be separated from the retention pads 20 by a secondary dielectric or solder mask 24. When multiple retention pads are used, they could have disposed thereon different types of connection solder 22 that mix together as they are drawn to the hole 12. Alternatively, a single type of connection solder 22 could be disposed on each retention pad 20 and the multiple retention pads could be used to better ensure that the solder 22 enters the hole 12 from different directions. In the latter case, the retention pads 20 would preferably be spaced around the hole 12 in a predetermined pattern. Alternatively, the retention pads 20 could all be positioned on a single side of the hole 12.

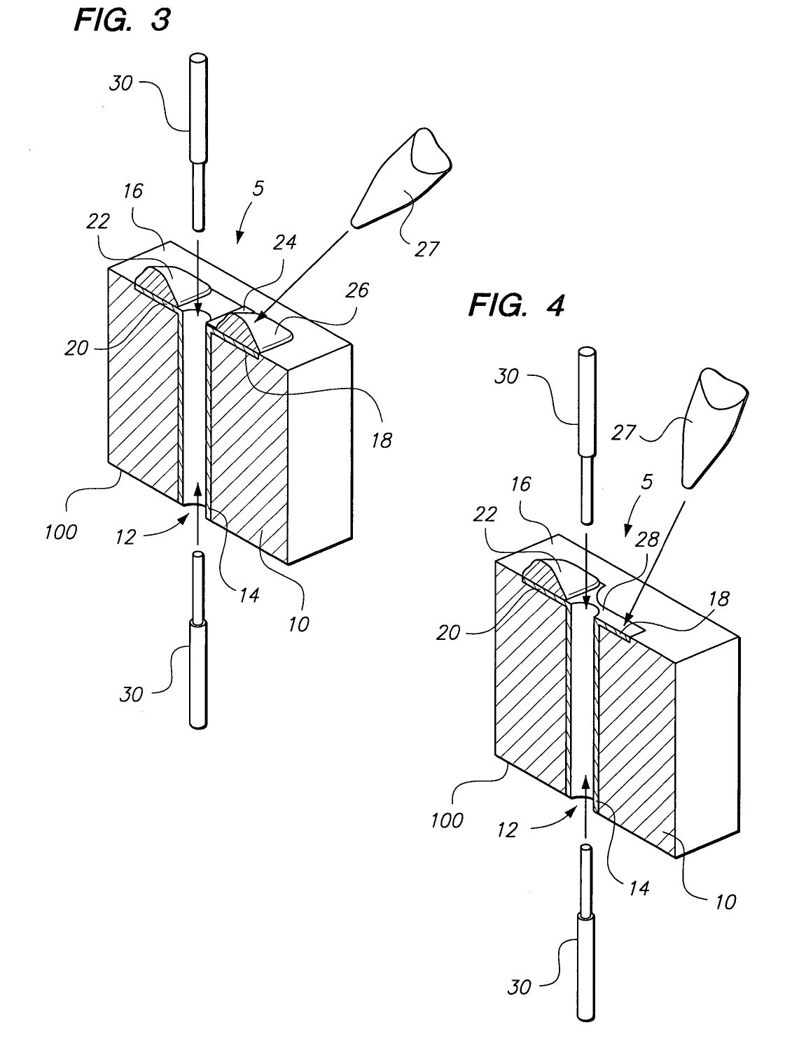

Referring to FIG. 3, heat transfer solder 26 is shown applied to the heat transfer pad 18 to enhance the heat transfer between the soldering iron tip and the heat transfer pad 18. The heat transfer solder 26 melts when heat is applied, but does not flow toward the opening of the hole 12 because of the solder mask 24.

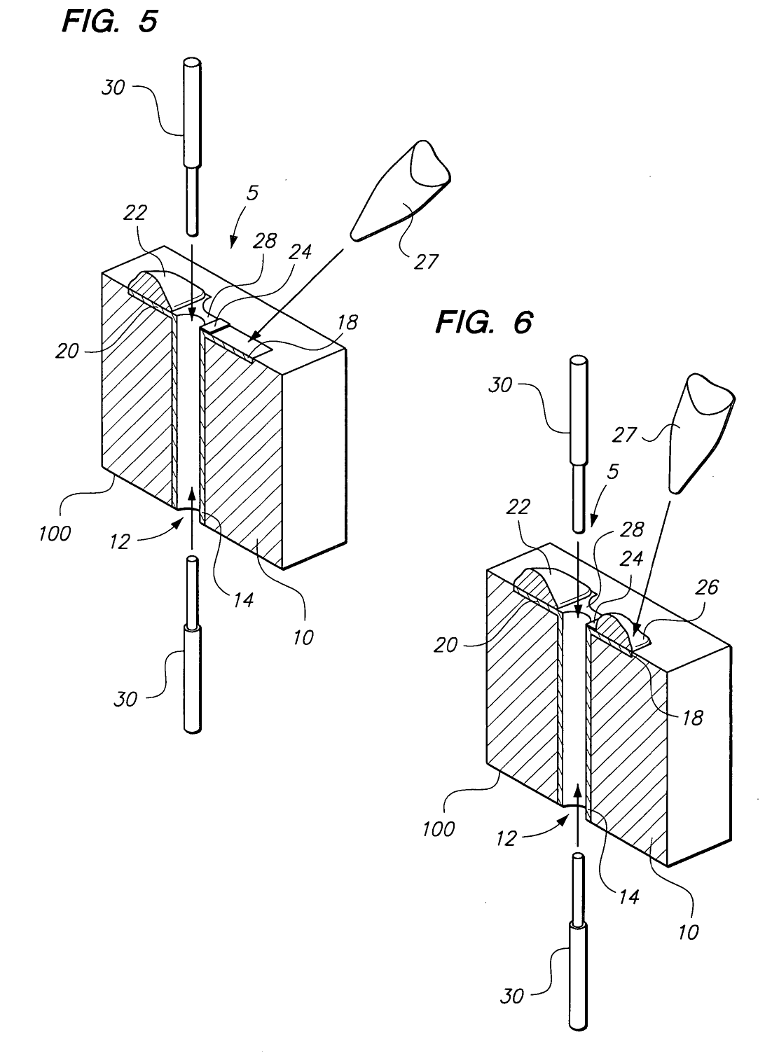

Referring to FIG. 4, as the connection solder 22 melts, it begins to flow towards the source of the heat being introduced into the system 5 and, in the process, covers and encapsulates everything also in thermal communication with the heat source. In order to aid in the encapsulation of the fine wire, a narrow pad can be used to increase the volume of the connection solder 22 at a given cross section. As such, system 5, as shown in FIG. 4, has a narrow heat transfer pad 28 that is contacted by the heat source 27. FIG. 5 illustrates the solder mask 24 adjacent to the narrow heat transfer pad 28, while FIG. 6 shows the heat transfer solder 26 applied to the narrow heat transfer pad 28. It will be recognized by those of ordinary skill in the art, that FIGS. 4, 5 and 6 are otherwise similar to the system shown in FIGS. 1, 2 and 3, except that the heat transfer pad 18 is narrowed.

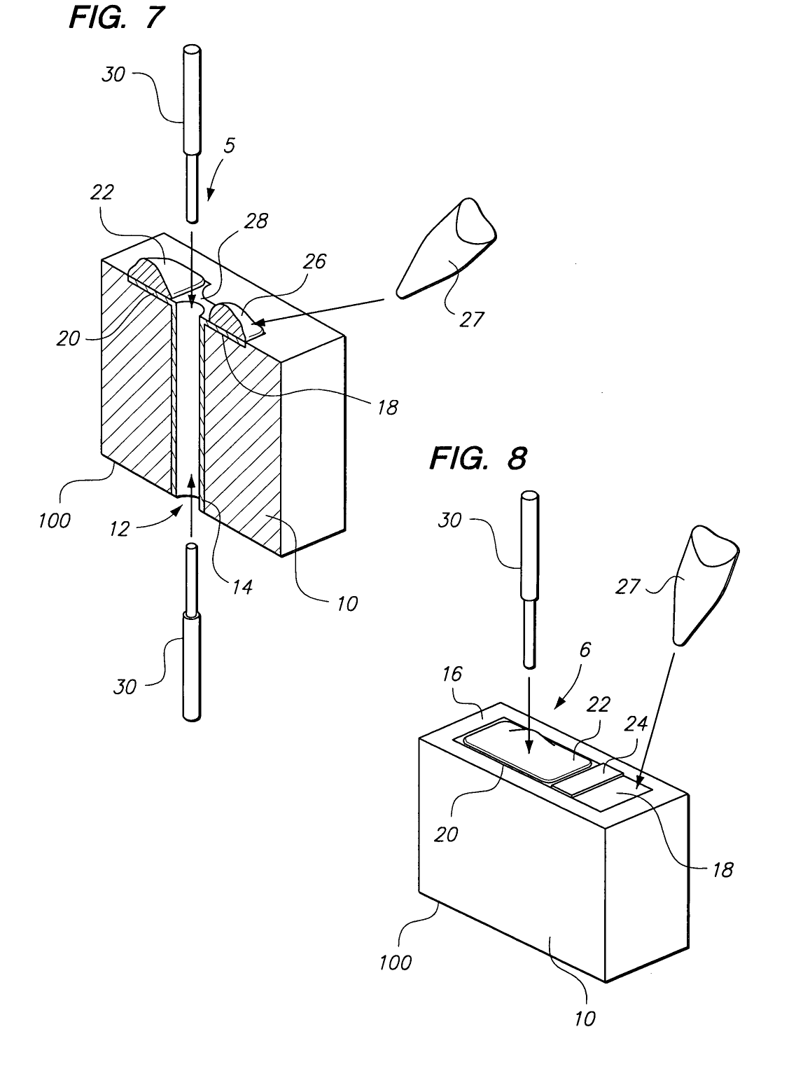

As shown in FIG. 7, in order to provide additional solder to the connection, it is possible to apply connection solder 20 from both the solder retention pad 20 and the heat transfer pad 18. Thus, in this embodiment, the heat transfer material 26 applied to the heat transfer pad 18 is used for both heat transfer and connection purposes. The heat source melts the connection solder 22 and the heat transfer material 26. Without the solder mask 24 separating the solder retention pad 20 and the heat transfer pad 18, the solder from the heat transfer pad 18 and retention pad 20 can flow over the wire inserted into the hole 12.

Referring to FIG. 8, a hot bar wire termination system 6 for putting a wire in electrical communication with other portions of a substrate 10 is shown. Termination system 6 has conductive plating 14 applied to the top surface 16 of the substrate 10. Conductive plating 14 forms the heat transfer pad 18 and the solder retention pad 20 such that they are in thermal communication with each other. Connection solder 22 is applied to the solder retention pad 20. Solder mask 24 prevents the connection solder 22 from flowing to the heat transfer pad 18.

In order to attach a fine wire or other component to the termination system 6, a heat source such as a soldering iron 27 initiates heat transfer to the heat transfer pad 18. The heat from the heat source 27 is transferred to the solder retention pad 20, which melts the connection solder 22. When the solder has melted, a flat wire or the end of a stripped and twisted tinned wire or other component lead is inserted into the connection solder 22. The heat source 27 is then removed from the heat transfer pad 18 and the connection solder 22 is allowed to cool and harden, thereby securing the wire to the solder retention pad 20. As previously mentioned, the solder mask 24 prevents the connection solder 22 from flowing back to the heat source 27. In addition, it prevents any solder residue that may exist on the heat source 27 from contaminating the connection solder 22.

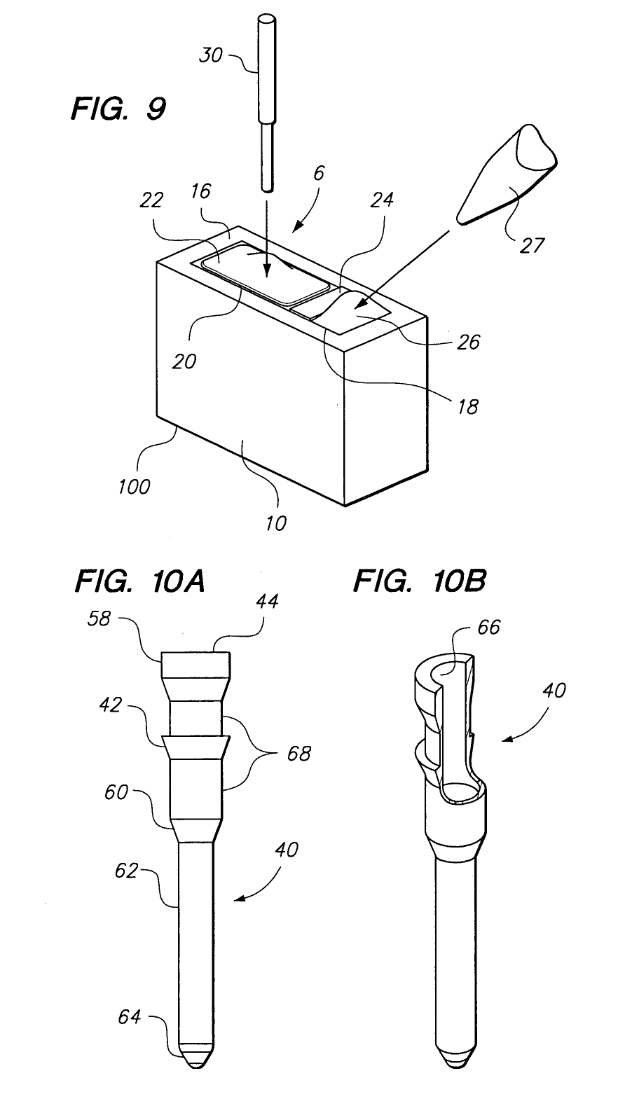

FIG. 9 illustrates the termination system 6 with the inclusion of the heat transfer solder 26 being applied to the heat transfer pad 18 in order to facilitate the thermal communication between the heat source 27 and the conductive plating 14. In another termination system 6 (not shown) similar to FIGS. 8 and 9, the heat transfer pad 18 is not used and the connection solder 22 is heated directly with the heat source 27. In yet another termination system 6, (not shown), more than one solder retention pad 20 is utilized in connection with a single or multiple heat transfer pads. In this example, the connection solder 22 positioned on each solder retention pad 20 may be the same or different. When the connection solders 22 are different, they may have a different thermal and/or electrical profile or characteristics. Heat applied to the heat transfer pad 18 communicates with each solder retention pad 20 to melt the connection solder thereon. The connection solder 22 from each retention pad mixes together and the component may be inserted into the mixed retention solder 22 to fix the component 30 to the substrate and the conductive material thereon.

FIGS. 10A and 10B depict a barbed pin that may be utilized with the example system. FIG. 10A depicts a pin 40 having a top end 44 and a tip end 64. The pin has a generally cylindrical shape. The pin includes several protrusions, including a top boss 58 and a barb 42. The top boss 58 is positioned at the top end 44, followed by a transition shoulder 60 to a transition boss 68. A barb 42 is positioned below the transition boss 68, followed by another transition boss 68 and transition shoulder 60. A connection tail 62 is positioned below the transition shoulder 60 and above the pin tip 64, which is tapered. FIG. 10B shows the pin of FIG. 10A, but with the upper part of the pin 40 cutaway to reveal a bore 66 in the top end 44 of the pin 40. The bore or hole 66 is a blind hole that extends from the top surface 44 longitudinally down the pin to an arbitrary distance. The hole 66 may have other lengths and dimensions and shapes than the cylindrical hole 66 depicted.

The protrusions 42, 58 on the pin 40 are utilized to generate mechanical interactions between the pin 40 and the hole 12 in the substrate 10 by the friction fit created between the hole 12 and the pin 40. When conductive material 14 is positioned inside the hole 12, the protrusions on the pin 40 act to bite into the conductive material 14. In this manner, the pin 40 establishes an electrical connection with the conductive material, which may be in contact with electrical traces (not shown) positioned on the substrate that are coupled to the hole 12. In addition, as shown below, a connection solder 22 may be positioned around the top end 44 of the pin 40. The solder 22 also aids in establishing an electrical connection between the pin 40 and the electrical traces on the substrate 10. In addition, the solder 22 helps to anchor the pin 40 in the hole 12 and provides better mechanical retention and cohesive strength. The one or more protrusions 42, 58 on the pin 40 are used to bite into the conductive material 14 in the hole 12, or into the side wall of the hole 12 when no conductive material is positioned inside the hole. The contact between the protrusions and the hole helps to keep the pin perpendicularly aligned with the substrate. Of the protrusions discussed herein, radial barbs 42 help to align the pin 40 perpendicular to the substrate better than other protrusion styles. This is particularly true in non-homogeneous substrate materials, such as FR-4 printed circuit board material.

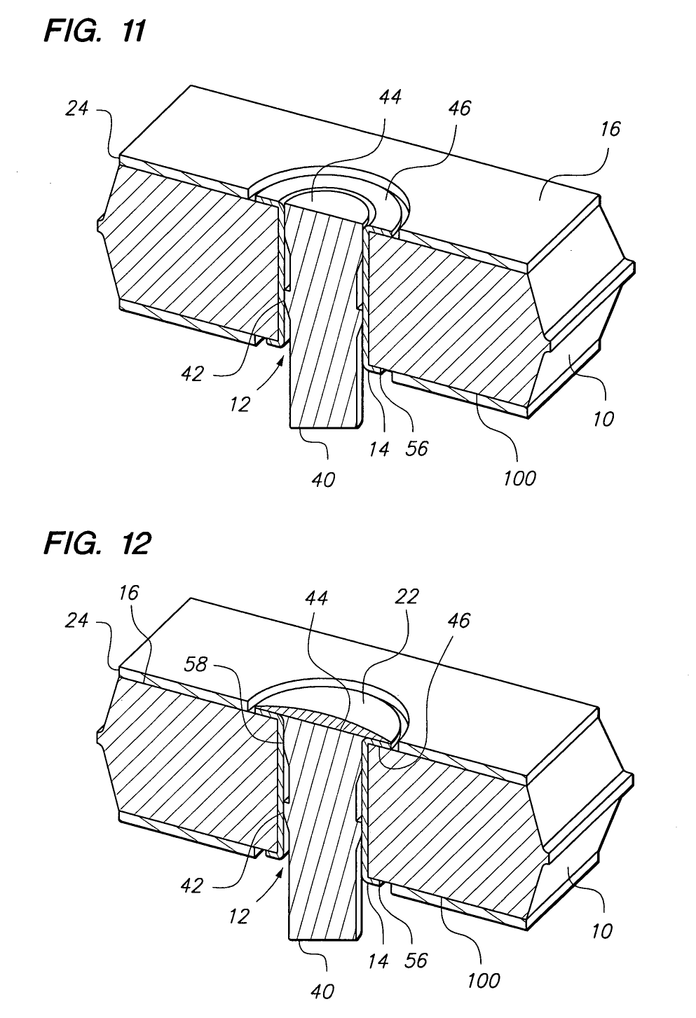

In FIG. 11, a barbed pin 40 is shown inserted into the hole 12 of a dielectric substrate 10, which has been coated with conductive plating 14 and may or may not be in electrical communication with the other features of the substrate 10. An annular structure 46 of conductive plating 14 is formed on a top surface 16 and a bottom surface 100 of the substrate 10 around the opening of the hole 12. Typically, the pin 40 is formed from a copper alloy with a barb 42 being disposed on an outer circumference thereof. However, the pin may be manufactured from any known conductive material. The barb 42 is sized slightly larger than the inner diameter of the hole 12 and tapers downwardly from the top surface 16 of the substrate 10. The barb 42 contacts the side walls of the hole 12 to provide an electromechanical connection with the conductive material 14 therewith. Furthermore, a top end 44 of the pin 40 is formed slightly larger than the inner diameter of hole 12 in order to contact the side walls of hole 12. Top end 44 and barb 42 of pin 40 provide for a friction fit between pin 40 and conductive plating 14 inside the hole 12. Solder mask 24 coats the top 16 and bottom 100 of substrate 10 to prevent solder 22 from flowing into or out of its designated areas. However, the solder mask 24 does not cover the annular structure 46 or the opening of the hole 12.

When two or more protrusions are provided, as shown in FIGS. 22B, 22C, 22D, 22E, 22F, 22J, 22K and 22L, the lower protrusion may have a slightly smaller diameter than the following protrusion. The lower protrusion may have a larger diameter than the top barb. The lower protrusion in many of these examples is a barb that has a shoulder positioned below the barb. The lower barb expands part of the hole. The second protrusion from the bottom may then have a larger diameter than the first protrusion so that it can bite into the interior surface of the hole after the hole size was expanded by the first, lower protrusion. If a third protrusion from the bottom is present, the third protrusion may have an even larger diameter than the second protrusion to also bite into the side walls of the hole.

In order to further secure the pin 40 within the hole 12 and significantly increase both the electrical communication between the pin 40 and the conductive plating 14, as well as the mechanical bond therebetween, the connection solder 22 is applied to the annular structure 46 and the top end 44 of the pin 40. Connection solder 22 can be applied using the mini wave system and method described above or by any other method desired.

FIG. 12 illustrates the connection solder 22 after it has been applied to the annular structure 46 and the top end 44 of the barbed pin 40. Connection solder 22 electrically and mechanically connects the pin 40 to the hole 12 and the annular structure 46. In this respect, the connection solder 22 prevents the pin 40 from being pushed upwards from the top surface 16 of the substrate 10.

FIG. 13 illustrates hole 12 having counter bore 48 formed at the top surface 16 of the substrate 10. Counter bore 48 allows additional connection solder 22 to be applied, as well as providing for a larger opening for the insertion of pin 40. As seen in FIG. 13, the counter bore 48 is also coated with the conductive plating 14.

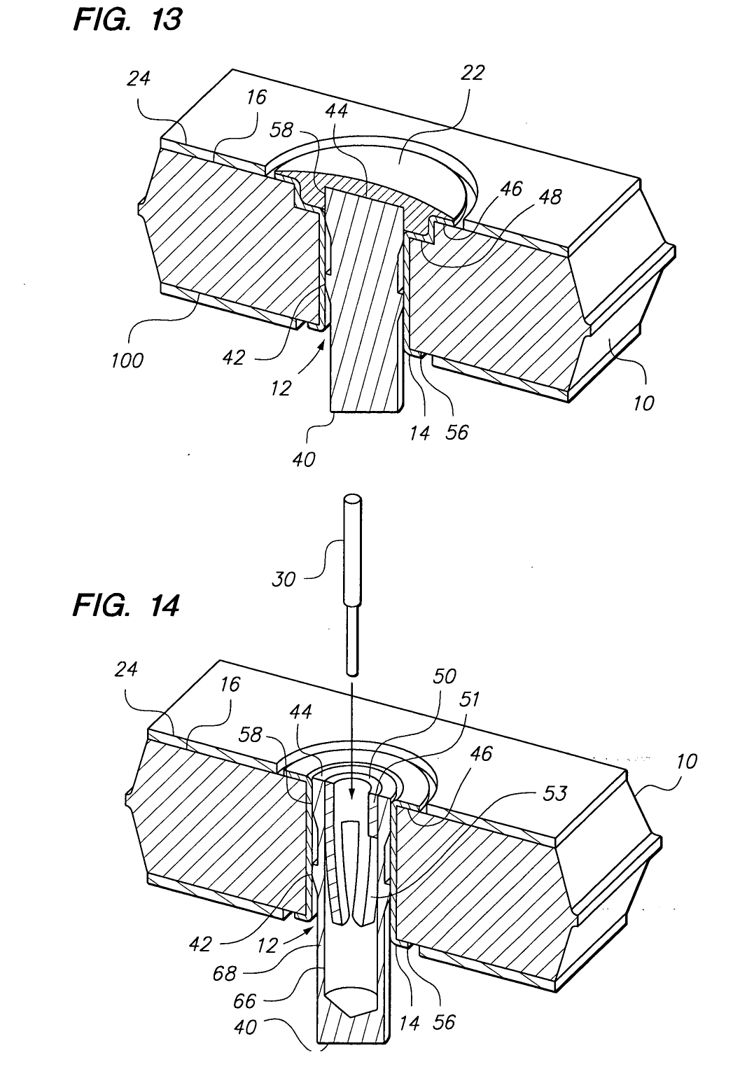

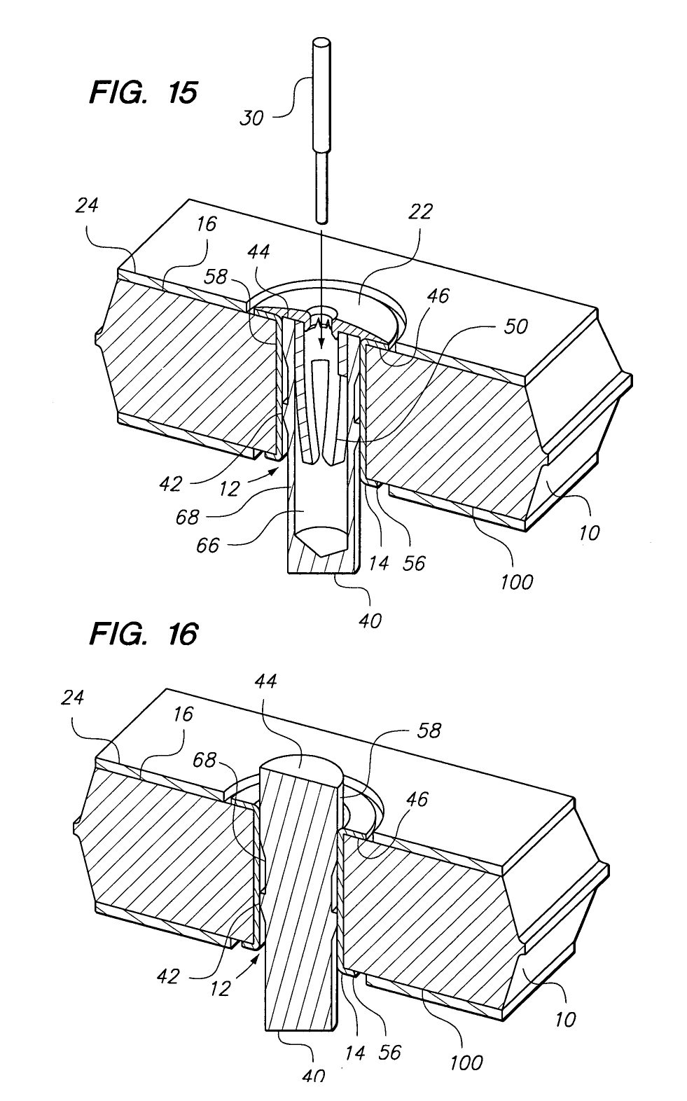

FIG. 14 illustrates the barbed pin 40 comprising a clip 50 or formed contact inserted into the hollow bore 66 that has been formed within the pin 40 at the top end of the pin. Clip 50 is a formed contact that is inserted into the inner bore of the pin 40. The clip 50 has a cylindrical upper end 51 with tines 53 that bend inwardly and extend down from the cylindrical upper end 51. The upper end 51 of the clip 50 is sized to be press fit into the bore 66 in the pin 40. The clip 50 is made of a conductive material. The bore 66 extends part of the way down the length of the pin 40. A wire or another pin 40 can be inserted into the clip 50, which would then provide for electromechanical communication between the clip 50 and what was installed therein. The clip 50 can be used to retain an electrical wire mechanically, to provide an electrical connection without solder, or as a temporary clamp during soldering. FIG. 15 shows how the connection solder 22 flows over the top end 44 of the pin 40, as well as the annular structure 46.

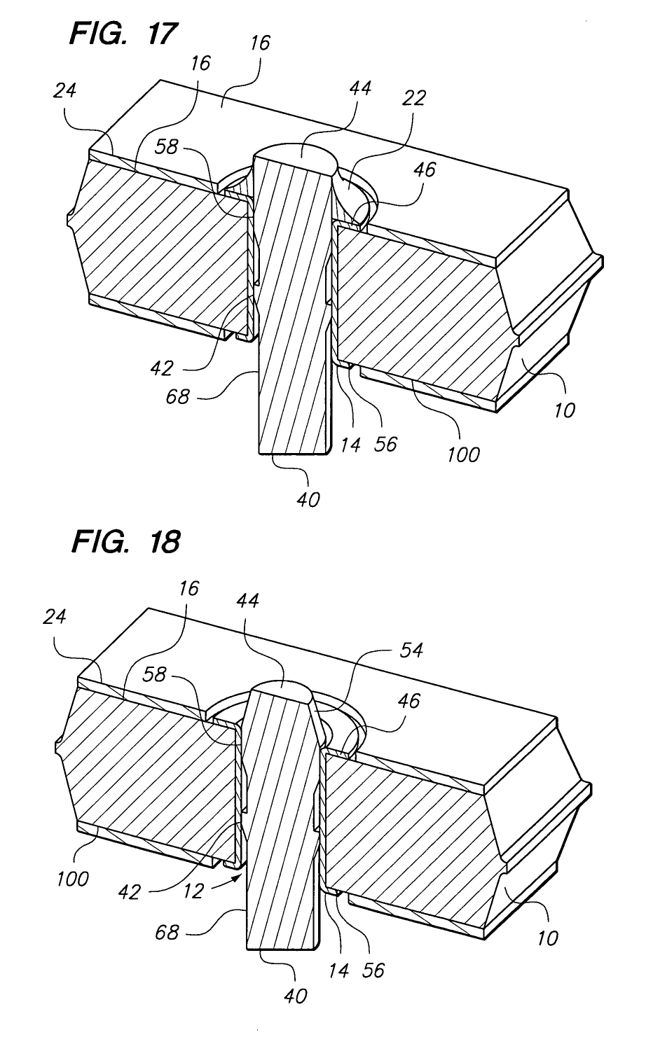

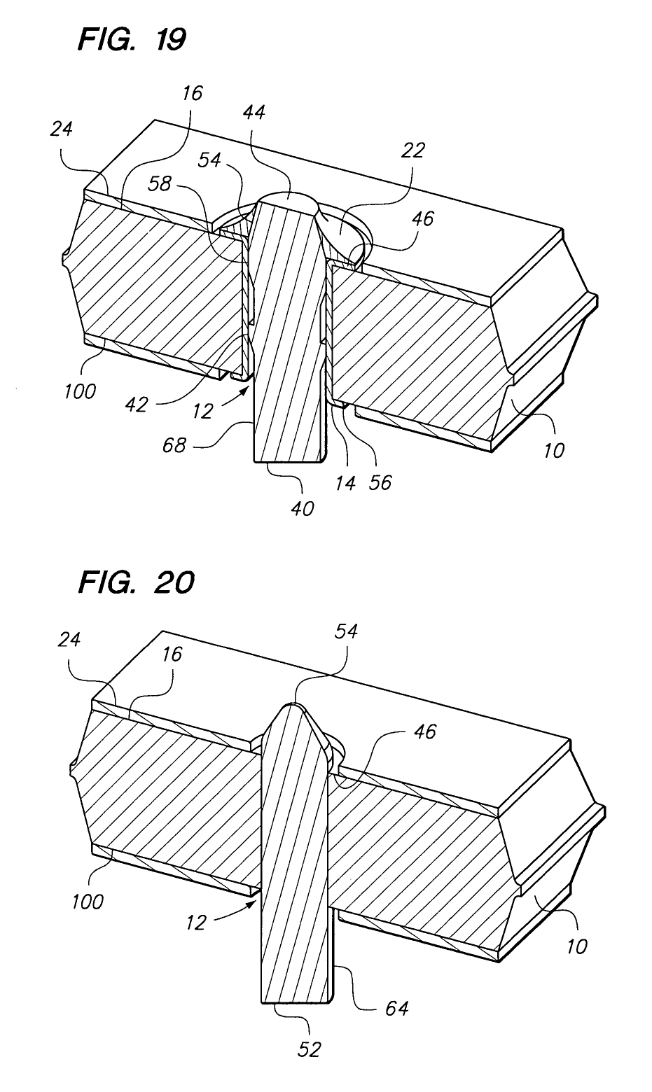

FIGS. 16 and 17 illustrate the top end 44 of the barbed pin 40 raised above the top surface 16 of structure 10. Raised top end 44 provides a point that a wire can be connected to the pin 40, if desired. Connection solder 22 flows around the raised top end 44 in order to secure the pin 40 to the annular ring 46 of the structure 10 in a much more mechanically sound way than was shown in FIG. 12. FIGS. 18 and 19 illustrate the raised top end 44 of the barbed pin 40 being tapered and soldered to the annular structure 46.

In addition to the foregoing, it is also possible to insert a non-barbed pin 52 through a hole 12 formed in the structure 10. As shown in FIG. 20, the non-barbed pin 52 has a tapered top end 54 extending through the top surface 16 of the structure 10. The bottom of this pin 52 may have a similar taper, which would allow the pin to be inserted into the hole 12 with either end being the top end. Hole 12 is not coated with the conductive plating 14 and the pin 52 is pressed into the hole 12 with an axial friction fit. Alternatively, plating could be utilized in the hole, or an eyelet or other insert could be used. In this example, because the hole is not lined with a conductive material, the thermal connection between the conductive material 14 on the top surface 16 of the substrate 10 could be provided by a solder, by a conductive adhesive, or by mechanical means, such as grippers or teeth.

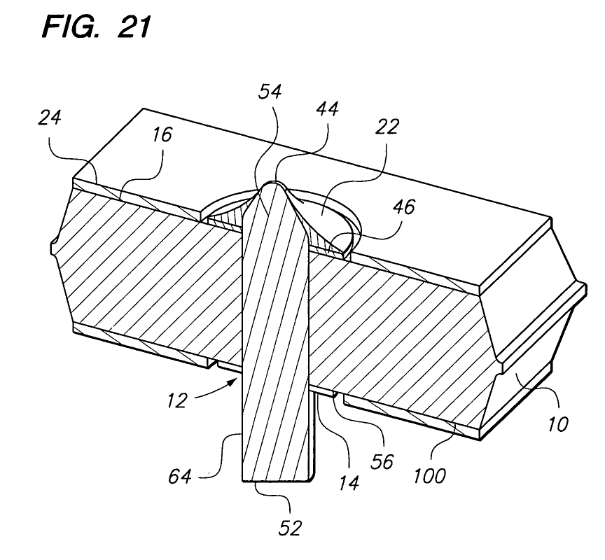

FIG. 21 illustrates the pin 52 being secured with the connection solder 22 around the top end 54 of the pin 52. In this respect, a top annular structure 46 of the conductive plating 14 is formed around the opening of the hole 12 on the top surface 16 of the substrate 10. Furthermore, a bottom annular structure 56 can be formed around the opening of the hole 12 on a bottom surface 100 of the substrate 10. Solder mask 24 controls and retains all the solder present on the substrate 10, as previously discussed. An electrical connection is established between the pin 40 and traces on a substrate 10 by the solder 22, which mechanically anchors the pin in the substrate 10 and electrically connects the pin 40 to any electrical traces present on the substrate 10 in communication with the solder 22.

Each of FIGS. 17-21 depicts a pin 40 where the top 44 of the pin 40 extends above the surface of the substrate 10 and connection solder 22 is disposed around the top 44 of the pin 40. In these examples, the mechanical bond of the pin 40 to the substrate 10 is further strengthened because when the pin 40 is pulled in the direction of through the substrate 10 and the solder 22 gets placed into the mechanical state called shear, the solder material itself 22 will need to fracture and to be sheared off the pin 40 for relative movement between the pin 40 and the substrate 10 to occur. As a result, the required forces are very high and the joint is made significantly stronger.

FIGS. 22A-22L depict various pin configurations for use with a PCB or other substrate 10. Pins 40 are typically used for carrying electrical current. The shape of the pins 40 may be used for many different functions. For example, the pins 40 may be used for mechanical retention in the substrate 10 so that the pin 40 does not push out or become loose. Pins 40 provide precise mechanical alignment perpendicular to the substrate. Where the top of the pin 40 and the bottom are different from one another, as the pin 40 is pressed into the substrate, each feature on the pin carves its own path. As a result, the pin 40 is held more firmly during the press fit and higher hoop stress retains the pin in the substrate 10. In versions of the pin 40 where the top boss 58 is press fit into the hole 12, there may be variations in the hole shape and in the shape of the boss 58 such that either or both of the hole shape and the boss shape are not identical. For example, the hole 12 or pin 40 may not be entirely round, or there may be small surface imperfections within the hole or on the surface of the pin 40. When connection solder 22 is applied to the top of the pin 40, solder 22 will enter these small imperfections in the surface or other irregularities between the pin 40 and the hole 12 in order to seal the area around the pin 40 with solder 22. This solder 22 around the pin 40 is more incidental, but helps to strengthen the mechanical bond to a degree. In other examples, grooves or other features on the pin 40 allow solder 22 to penetrate the joint between the hole 12 and the pin 40 to make the joint stronger. Also, different shapes work better in different materials. Some designs are lower cost than others. All of these considerations must be taken into account when designing and selecting a pin configuration.

It should be noted that there may be cases where the top cylindrical boss 58 has a diameter such that it is not press fit into the hole 12. In these instances, solder 22 can flow around the top of the pin 40 down to the barbs 42 to provide additional mechanical retention of the pin 40 relative to the substrate 10. The solder 22 acts like a glue to hole 12 the pin 40 in place whether it is positioned on a side of the pin 49 within the hole 12 or on the top 44 of the pin 40.

FIG. 22A depicts a pin 101 having an elongated body with a protrusion positioned in the upper portion of the pin 40 in the form of a cylindrical boss 58. The boss 58 is positioned at a top end 44 of the pin 101. A transition shoulder 60 is positioned below the boss 58, followed by a cylindrical transition boss 68, followed by another transition shoulder 60. The transition shoulders are essentially cone-shaped where the pin is cylindrical, as in this case. The lower part of the pin 40 includes a connection tail 62 coupled to the pin tip 64, which is tapered. In this example, the boss 58 is preferably slightly larger than the hole opening 12 such that the boss 58 is press fit into the opening. This example pin 101 does not include a barb.

FIG. 22B depicts a tapered pin 102. The top end 44 of the pin 102 has a tapered top end 54 and the lower end of the pin 102 has a tapered tip 64. The diameter of the pin 40 at the upper end (at 58) is greater than the diameter of the pin 40 at the lower end (at 62). The tapered top 54 is joined to a protrusion in the form of a top boss 58, which is followed by a transition shoulder 60 and by a transition boss 68. Two protrusions in the shape of barbs 42 are positioned below the transition boss 68 and are separated and followed by another transition boss 68. The lowermost transition boss 68 is followed by a transition shoulder 60 and the connection tail 64 of the pin 102. The barbs 42 and top boss 58 may have a similar diameter that is greater than the diameter of the hole 12, such that when the pin 102 is inserted into the hole 12, a friction fit is provided equally at each protrusion. Alternatively, the boss 58 and barbs 42 could have different diameters such that one of the boss or the barbs engages the conductive coating 14 of the hole 12 in a different frictional manner than the other. One protrusion could bite into the conductive coating 14 more than another, if desired. The same is true for any of the following examples where the barbs 42 and bosses 58 may have similar diameters. In each case, they may also have different diameters so that the various protrusions 42, 58 have different frictional engagements with the hole 12 that they are positioned inside.

As shown below in connection with several of the example pins 40, the pin 40 has an upper portion and a lower portion, with protrusions 42, 58 that extend outwardly from the elongated body being substantially positioned in the upper portion. The protrusions 42, 58 may have different shapes and different diameters. Alternatively, they may have the same diameters. The diameter of the protrusions 42, 58 affects the amount of biting into the conductive material that is performed by the protrusion when the pin 40 is press fit into the hole 12. In addition, the protrusions 42, 58 may hit the substrate 10 within the hole 12 at different clockings, such as a first set of barbs 42 or features 58 might hit at 12, 4, and 8 o'clock and a second set of features 42, 58 might hit the substrate at 2, 6, and 10 o'clock. Additionally, the first set might have a smaller diameter than the second set. All of these techniques means that more “hoop stress” or force is pushing from the substrate 10 onto the pin 40 and holding them in place more securely and accurately.

FIG. 22C depicts an asymmetric pin 103. The top end 44 of the pin 103 has a protrusion in the form of an asymmetric top boss 58. The asymmetric top boss 58 has wing-like structures 59 that extend outwardly from a central circular portion 61, to provide gaps between each wing 59. The top boss 58 is followed by a transition portion 68, which is followed by a barb 42 and another transition portion 68. The lowermost transition portion is followed by a transition shoulder 60, which is followed by the connection tail 62 and pin tip 64, which is tapered. The top boss 58 and barb 42 preferably have a similar diameter that is larger than the diameter of the hole 12, so that when the pin 103 is inserted into the hole 12, the top boss 58 of the pin 103 is press fit into the hole 12 and the barb 42 grips the side of the hole 12. In this example, when solder 22 is applied to the top end 44 of the pin 103, solder may flow between the wings 59 all the way down to the barb 42. This design promotes mechanical strength of the joint, among other benefits.

FIG. 22D depicts a polygon pin 104, where the protrusion is in the form of the top boss 58 having a polygonal shape. The top boss 58 is followed by a transition shoulder 50, followed by a transition portion 68, followed by a barb 42. The transition portions 68 are cylindrical and the transition shoulder 60 is cone-shaped. The barb 42 is followed by another transition portion 68 and transition shoulder 60, which is followed by the connection tail 62 and pin tip 64, which is tapered. The top boss 58 and barb 42 preferably have a similar diameter that is larger than the diameter of the hole 12, so that when the pin 104 is inserted into the hole 12, the top boss 58 of the pin 104 is press fit into the hole 12 and the barb 42 grips the sides of the hole 12. In this example, when solder 22 is applied to the top end 44 of the pin 104, solder 22 may flow between the edges of the polygon 58 all the way down to the barb 42. This design promotes mechanical strength of the joint, among other benefits.

FIGS. 22E and 22F are similar to FIGS. 22C and 22D, except for FIG. 22E depicts a pin 105 with a protrusion in the form of a triangular top boss 58 and FIG. 22F depicts a pin 106 with a protrusion in the form of a rectangular top boss 58. In both of these examples, as discussed above, solder 22 may flow between the edges of the top boss 58 and the sides of the hole 12 until the solder 22 reaches the barb 42. These designs also promote mechanical strength of the joint, among other benefits.

FIG. 22G depicts a double formed pin 107 that has an upper part of the top boss 58a, which is positioned at the top end 44 of the pin 107, and a lower part of the top boss 58b, which is positioned directly below the upper part of the top boss 58a. The upper and lower parts of the top boss 58a, 58b are protrusions that extend outwardly from the elongated body of the pin. The upper part of top boss 58a has a cross-sectional cross-shape and the lower part of top boss 58b has a cross-sectional cross-shape, but the cross-shapes of the upper and lower parts 58a, 58b are staggered such that only the top cross is visible in the top view. A transition shoulder 60 is positioned below the lower part 58b, followed by the connection tail 62 and pin tip 64, which is tapered. In this pin 107 design, the top boss 58a, 58b preferably has a diameter that is larger than the diameter of the hole 12 such that the pin 107 must be press fit into the hole 111. Solder 22 may flow between the legs of the cross-shape to promote mechanical strength in the joint between the conductive material 14 of the hole 12 and the pin 107. Pin 107 does not depict barbs 42, but barbs could also be utilized, if desired.

FIG. 22H is a knurled pin 108 that has a protrusion in the form of a knurled boss 58 at the top end 44. The knurled boss 58 is coupled to the connection tail 62 and pin tip 64 by a transition shoulder 60. In this pin 108 design, the top boss 58 preferably has a diameter that is larger than the diameter of the hole 12 such that the pin 108 is press fit into the hole 12. Solder 22 may flow along the knurled surface of the top boss 58 to promote mechanical strength in the joint between the conductive material 14 of the hole 12 and the pin 108. Pin 108 does not depict barbs 42, but barbs 42 could also be utilized, if desired.

FIG. 221 depicts a protrusion in the form of a quad formed pin 109, where the top boss 58 has a cross-shaped cross-section, followed by a transition shoulder 60, the connection tail 62, and the pin tip 64, which is tapered. The top boss 58 preferably has a diameter that is larger than the diameter of the hole 12 such that the pin 109 is press fit into the hole 12. Solder 22 may flow between the legs of the cross-shape to promote mechanical strength in the joint between the conductive material 14 of the hole 12 and the pin 109. Pin 109 does not depict barbs 42, but barbs 42 could also be utilized, if desired.

FIG. 22J depicts a pin 110 having two protrusions in the form of a boss 58 and a single barb 42 and FIG. 22K is a pin 111 having three protrusions in the form of a top boss 58 and multiple barbs 42. In each case, the top boss 58 is followed by a transition shoulder 60, which is followed by a transition boss, which is followed by the barb 42. The protrusions in FIGS. 22J and 22K may have the same or different diameters.

In FIG. 22K, the top most barb 42 is followed by a transition boss 68 and the second barb 42. After the lower most barb, both pins 110, 111 have a transition boss 68, followed by a transition shoulder 60, followed by a connection tail 62 and a pin tip 64, which is tapered. The outer diameters of the top boss 58 and barbs 42 are similar and are larger than a diameter of the hole 12, such that the pins 110, 111 are held in the holes 12 by a friction fit.

FIG. 22L is a pin 112 having protrusions in the form of a top hat 58a, a top boss 58b, and a barb 42. The top hat 58a has a larger diameter than both the barb 42 and the top boss 58b. The barb 42 and top boss 58b have a similar diameter to one another which is slightly larger than the opening of hole 12. When pin 112 is inserted into hole 12, the top hat 58a seats on the top surface 16 of the substrate 10, while the top boss 58b and barb 42 are press fit into the hole 12. The top boss 58b is coupled to a transition shoulder 60, which is coupled to a transition boss 68, which is coupled to the barb 42. The barb 42 is coupled to a transition boss 68, followed by a transition shoulder 60, followed by the connection tail 62 and pin tip 64, which is tapered.

While not shown, a pin 40 could be provided that has a barb 42 that extends the entire length of the elongated body. The barb could be like that depicted in FIG. 10A as reference number 42, or could have a varying peripheral shape.

While the above has been discussed primarily in connection with the soldering of a wire 30 to a termination point, it should be understood that any type of component 30 may derive an advantage from the aforementioned description. The terms “wire” and “component” are defined to include resistors, capacitors, inductors, light emitting diodes, diodes, transistors, FET's, integrated circuits, pins, wires, cables, sockets, switches, any gauge of wire, and any other components known by those of skill in the art to be applicable to a PCB. Therefore, the term wire is not to be limited to a wire and is defined to include any type of component that may be connected to a dielectric substrate.

While the hole 12 described above was shown as a cylindrical hole having a round cross-section, the hole may be any shape including, but not limited to, round, square, hexagonal, slotted, counter-bored, counter-sunk, drilled, routed, stamped, swaged, cut, and the like. The substrate 10 was depicted as a single board, however, it will be recognized by those of skill in the art that the examples disclosed herein are equally applicable to a multi-layer substrate 10.

The term “substantially” as used herein is a term of estimation.

It will be appreciated by those of ordinary skill in the art that the concepts and techniques described herein can be embodied in various specific forms without departing from the essential characteristics thereof. The presently disclosed examples are considered in all respects to be illustrative and not restrictive. The scope of the invention is indicated by the appended claims and all changes that come within the meaning and range of equivalents thereof are intended to be embraced.

1. A mini wave solder system comprising:
a dielectric substrate having a hole defined therethrough, with a conductive material associated with the hole;
a conductive heat transfer pad disposed adjacent to the hole for communicating with a thermal transmitter; and
a conductive retention pad disposed adjacent to the hole and coupled to the heat transfer pad, the retention pad having a thermally activated conductive material positioned thereon,
wherein the heat transfer pad, the retention pad, and the hole are in thermal communication with each other.

2. The system of claim 1, wherein said hole has an inner wall that is coated with a conductive material, or the hole has a conductive insert positioned therein.

3. The system of claim 1, wherein the heat transfer pad is contained within the substrate, or positioned on a surface of the substrate.

4. The system of claim 1, wherein the thermally activated conductive material is a connection solder.

5. The system of claim 4, wherein the hole is shaped and sized to receive a component therein, the component being secured by the connection solder changing from a liquid to a solid state.

6. The system of claim 5, further comprising a secondary dielectric substance disposed between the opening of the hole and the heat transfer pad, wherein the secondary dielectric substance prevents contamination between the connection solder and a thermal transmitter in physical contact with the heat transfer pad.

7. The system of claim 5, wherein the retention pad comprises a plurality of retention pads, each of which has a connection solder associated therewith, and the heat transfer pad is thermally coupled to each of the plurality of retention pads, with a secondary dielectric being positioned between the heat transfer pad and the hole.

8. The system of claim 6, wherein the secondary dielectric controls the amount of solder that interacts with the component.

9. The system of claim 7, wherein each of the plurality of retention pads are associated with a different one of a plurality of connection solders, with each connection solder having a different thermal profile than the other connection solders such that upon the application of heat to the heat transfer pad, the plurality of connection solders melt and mix together as they travel into the hole around the component.

10. The system of claim 4, further comprising heat transfer material positioned on the heat transfer pad in order to facilitate heat transfer between a thermal transmitter and the heat transfer pad.

11. The system of claim 10, wherein the heat transfer material has a different thermal profile from the connection solder.

12. The system of claim 4, wherein the heat transfer pad has a first width and the retention pad has a second width, and one of the first width is different from the second width in order to modulate the thermal communication between the heat transfer pad and the retention pad and the thermal modulation controls the flow of the connection solder, or the first width is the same as the second width.

13. The system of claim 12, further comprising a secondary dielectric substance disposed between the opening of the hole and the heat transfer pad.

14. The system of claim 12, further comprising connection solder applied to the heat transfer pad.

15. A method for coupling a component to a substrate having a hole comprising:
providing a mini wave solder system according to claim 1,
inserting a component into the hole;
applying heat to the heat transfer pad via a an external heat source such that thermal energy travels from the heat transfer pad to the retention pad to melt the thermally activated conductive material, which, upon melting, flows toward the heat source and enters the hole to surround the component; and
removing the heat source from the heat transfer pad and allowing the mini wave solder system to cool in order to fix the component in the hole.

16. A wire termination system comprising:
a dielectric substrate having a surface;
a conductive material disposed on the surface of the dielectric substrate, the conductive material comprising a retention pad and a heat transfer pad in thermal communication with one another; and
a thermally activated conductive material positioned on the retention pad;
wherein when heat is applied to the heat transfer pad, thermal energy travels to the retention pad to melt the thermally activated conductive material in order to secure a component to the conductive material.

17. The system of claim 16, further comprising a secondary dielectric material disposed between the retention pad and the heat transfer pad, the secondary dielectric material being configured to prevent the thermally activated conductive material from flowing to the heat transfer pad.

18. The system of claim 16, wherein a plurality of retention pads are provided, with the heat transfer pad being thermally coupled to each of the plurality of retention pads.

19. The system of claim 16, further comprising heat transfer solder applied to the heat transfer pad.

20. The system of claim 19, wherein the heat transfer solder and the connection solder have differing thermal profiles.

21. A method for coupling a component to a dielectric substrate in a wire termination system comprising:
providing the wire termination system of claim 16;
applying a heat source to the heat transfer pad to melt the thermally activated conductive material disposed on the retention pad;
inserting a component into the melted thermally activated conductive material;
removing the heat source from the heat transfer pad and allowing the thermally activated conductive material to cool to secure the component to the substrate.

22. A pin connection system for coupling a pin to a dielectric substrate comprising:
a dielectric substrate having a hole disposed therethrough, with electrical traces defined on a surface of the substrate;
a pin positioned in the hole having at least one radial protrusion disposed on an outer periphery thereof, said radial protrusion for aligning the pin with the substrate and for retaining the pin in the substrate in a substantially immobile manner; and
connection solder disposed on a top surface of the pin, wherein the solder strengthens the mechanical connection of the pin to the substrate and electrically connects the pin to the traces on the substrate.

23. The pin connection system of claim 22, wherein the pin comprises:
an elongated body;
with the radial protrusion having a size and shape for frictionally engaging an interior side wall of the hole.

24. The pin connection system of claim 23, wherein the interior of the hole is associated with a conductive material that is electrically connected to the surface of the substrate, such that an electrical connection is further established between the pin and the conductive material in the hole by the frictional engagement of the pin with the interior side wall of the hole.

25. The pin connection system of claim 22, wherein a single radial protrusion is positioned at a substantially upper portion of the body, and the radial protrusion is selected from the group comprising a double formed boss, a knurled boss, a quad formed boss, a cylindrical boss, a square boss, a triangular boss, a polygonal boss, an asymmetrical boss, and a barb.

26. The pin connection system of claim 22, wherein the radial protrusion comprises a plurality of radial protrusions positioned on a substantially upper portion of the body, and the radial protrusions are selected from the group comprising one or more of a barb, a double formed boss, a knurled boss, a quad formed boss, a cylindrical boss, a square boss, a triangular boss, a polygonal boss, and an asymmetrical boss.

27. The pin connection system of claim 22, wherein the radial protrusion comprises multiple protrusions and at least one of 1) the protrusions are symmetrically spaced around a top end of the body, 2) the protrusions are asymmetrically spaced around a top end of the body, and 3) the protrusions are a plurality of knurls spaced around a top end of the body.

28. The pin connection system of claim 22, wherein the protrusion extends axially beyond a top end of the pin, or comprises a top end of the pin.

29. The pin connection system of claim 22, wherein the protrusion comprises a plurality of barbs, with each barb having a different frictional engagement of the hole.

30. The pin connection system of claim 22, wherein the protrusion comprises multiple protrusions, with each having different frictional engagements within the hole and the frictional engagements provide for at least one of the following: mechanical retention of the body within the hole, thermal communication of the body with the hole, and mechanical alignment of the body within the hole.

31. The pin connection system of claim 23, further comprising a hollow bore formed in the elongated body and a clip inserted into said bore.

32. The pin connection system of claim 23, wherein the top end of the body is tapered, and the bottom end of the body is tapered.

33. The pin connection system of claim 22, wherein a top end of the pin extends below a surface of the substrate, or a top end of the pin is flush with a surface of the substrate, or a top end of the pin extends above a surface of the substrate.

34. The pin connection system of claim 23, wherein the radial protrusion comprises a first barb positioned below a second barb on the elongated body, wherein the first barb has a first diameter sized and shaped to expand part of the hole as the pin enters the hole, and the second barb has a second diameter that is greater than the first diameter in order to bite into the substrate.

35. The pin connection system of claim 22, wherein connection solder is further disposed on a side of the pin within the hole to aid in mechanical retention and immobility of the pin within the hole.

36. The pin connection system of claim 22, wherein the radial protrusions allow for electrical communication with the traces on the substrate without the use of connection solder.

37. The system of claim 5, wherein multiple heat transfer pads are in communication with at least one retention pad.
